(19) United States
(12) Patent Application Publication
(10) Pub. No.: US 2024/0337947 A1
(43) Pub. Date: Oct. 10, 2024

(54) METHOD OF MANUFACTURING SEMICONDUCTOR DEVICE

(71) Applicant: TAIWAN SEMICONDUCTOR MANUFACTURING COMPANY, LTD., Hsinchu (TW)

(72) Inventors: Yuan Chih LO, Hsinchu City (TW); Ming-Hui WENG, New Taipei City (TW); Cheng-Han WU, Taichung City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/298,114

(22) Filed: Apr. 10, 2023

(51) Int. Cl. G03F 7/38; G03F 7/004; H01L 21/033; H01L 29/66

(52) U.S. Cl. CPC G03F 7/38; G03F 7/0042; H01L 21/0337; H01L 29/66545; G03F 7/2004; H01L 21/0332; H01L 29/66795

(57) ABSTRACT

A method of manufacturing a semiconductor device includes the following operations. A metal oxide photoresist layer is formed over a target layer. The metal oxide photoresist layer comprises a metal oxide core with organic ligands, a metal oxide framework with organic ligands, or a combination thereof. The metal oxide photoresist layer is exposed to an extreme ultraviolet radiation. The metal oxide photoresist layer is treated with a ligand leaving promoter. The metal oxide photoresist layer is developed to form a patterned photoresist. The target layer is etched by using the patterned photoresist as an etching mask.

### BACKGROUND

As consumer devices have gotten smaller and smaller in response to consumer demand, the individual components of these devices are decreased in size as well. Semiconductor devices, which make up a major component of devices such as mobile phones, computer tablets, and the like, have been pressured to become smaller and smaller, with a corresponding pressure on the individual devices (e.g., transistors, capacitors, resistors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that is not exposed, can be exploited to remove one region without removing the other. However, as the semiconductor industry has progressed into nanometer technology process nodes in pursuit of higher device density, higher performance, and lower costs, there have been challenges in reducing semiconductor feature size.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of an extreme ultraviolet (EUV) lithography system with a laser-produced plasma-based (LPP-based) EUV radiation source, in accordance with some embodiments of the present disclosure.

FIG. 1B is a simplified schematic diagram of a detail of an extreme ultraviolet lithography tool according to an embodiment of the disclosure showing the exposure of photoresist coated substrate with a patterned beam of EUV light.

FIG. 2 is a sectional view of a EUV mask in accordance with some embodiments of the present disclosure.

FIGS. 3-7 are diagrammatic fragmentary cross-sectional side views of a semiconductor device at various stages of fabrication in accordance with various aspects of the present disclosure.

FIG. 8A is a perspective view of a semiconductor device at various stages of fabrication in accordance with various aspects of the present disclosure.

FIG. 8B is a cross-sectional view of a semiconductor device taken along a line a1-a1 of FIG. 8A.

FIG. 8C is a cross-sectional view of a semiconductor device taken along a line b1-b1 of FIG. 8A.

FIGS. 9-12 are diagrammatic fragmentary cross-sectional side views of a semiconductor device at various stages of fabrication in accordance with various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

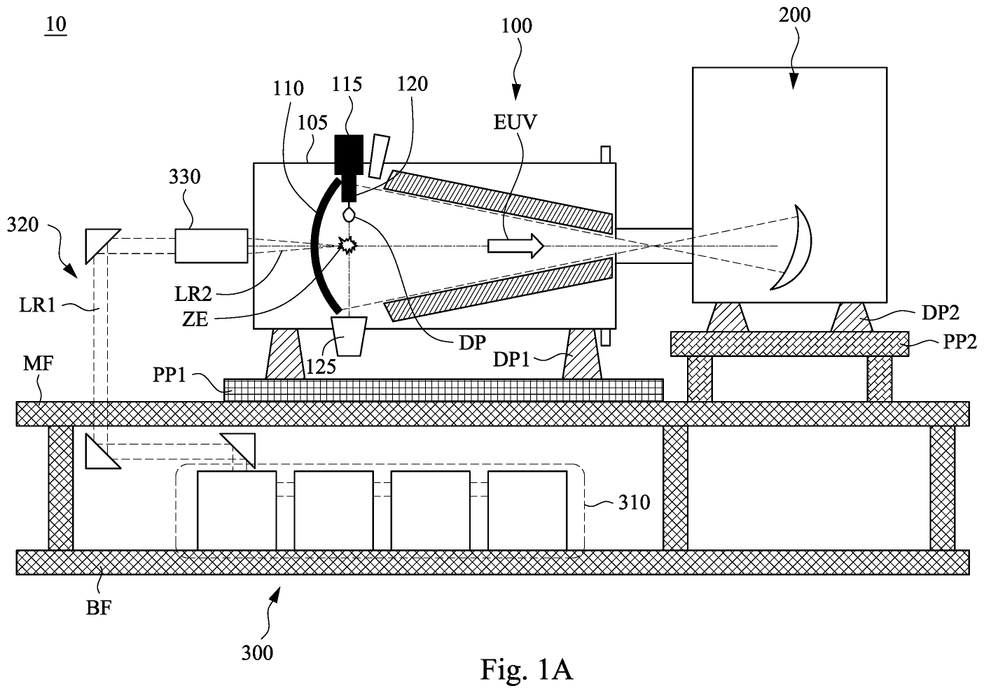

FIG. 1A is a schematic view diagram of an extreme ultraviolet (EUV) lithography system 10 with an laser-produced plasma based (LPP-based) EUV radiation source in accordance with some embodiments. The EUV lithography system 10 may also be generically referred to as a scanner that is configured to perform lithography exposure processes with respective radiation source and exposure mode. The EUV lithography system 10 is designed to expose a photoresist layer by EUV light or EUV radiation. The photoresist layer is a material sensitive to the EUV light. The EUV lithography system 10 employs a radiation source 100 to generate EUV light, such as EUV light having a wavelength ranging between about 1 nm and about 100 nm. In one particular example, the radiation source 100 generates a EUV light with a wavelength centered at about 13.5 nm. Accordingly, the radiation source 100 is also referred to as EUV radiation source.

EUV lithography can form delicate patterns with small pitches. The utilization of EUV cannot only shrink the pattern size but also reduce the repeating lithography-etch processes, which is beneficial for throughput and cost. However, when the pitches become small, defect issue associated with the photoresist is more critical. Nowadays, the traditional chemically resist (CAR) faces several problems, for example, line collapse induced by poor mechanical strength of photoresist polymers and poor EUV sensitivity. Metal oxide photoresists are developed due to their high mechanical strength and high sensitivity to EUV.

Materials of a metal oxide photoresist can absorb an electromagnetic wave, and therefore secondary elections and radicals can be generated during organic ligand dissociation. After the exposure, a post-exposure bake (PEB) is performed to intensify the organic ligand dissociation and dehydration of the metal oxide photoresist. Therefore, the metal oxide photoresist becomes dense and insoluble to a developer during developing stage. Based on this, reducing sizing dose and broken defects of photoresist patterns can be achieved by increasing dissociation ratio of the ligand and the mechanical strength of the photoresist.

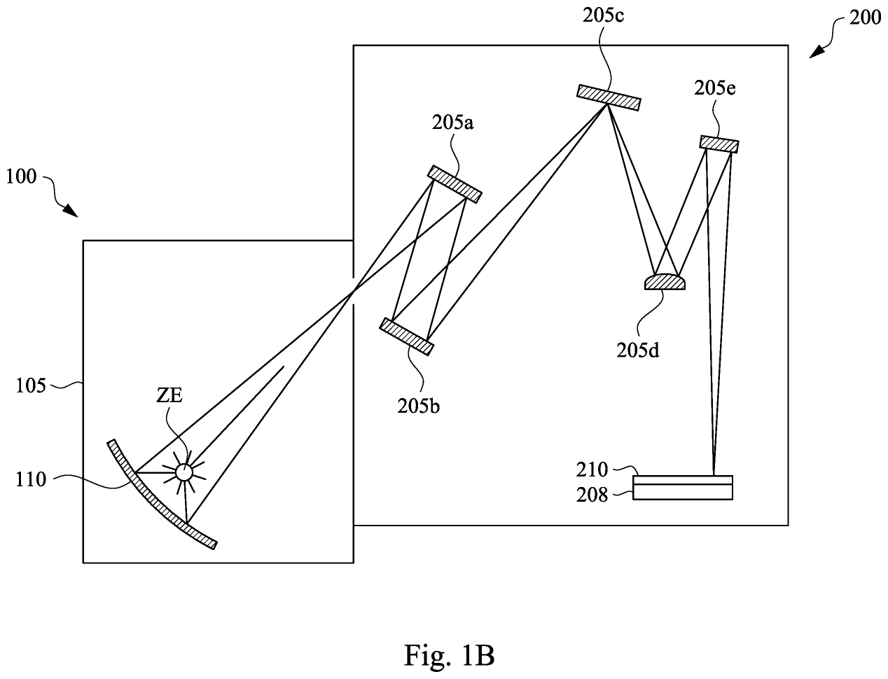

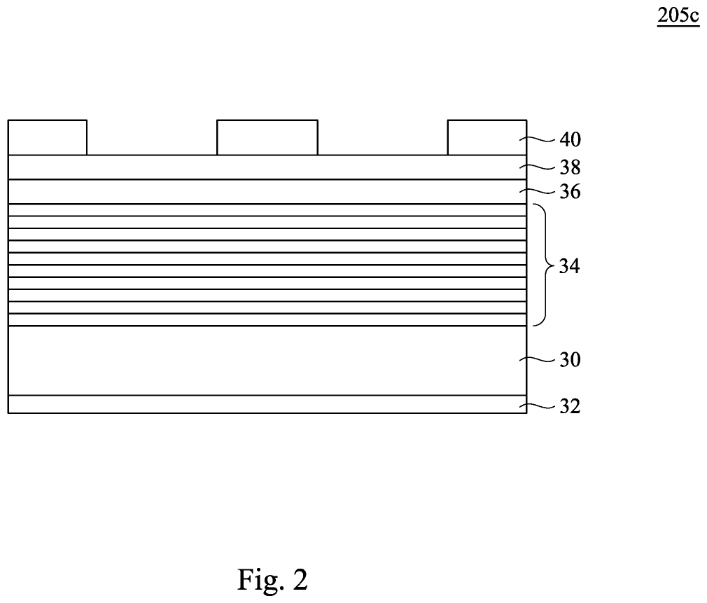

The present disclosure provides a ligand leaving promoter that can promote metal ligand bond cleavage in the photoresist and also provides a photoresist-strengthening material that can fill pores within the photoresist and cover an exterior surface thereof. The ligand leaving promoter and the photoresist-strengthening material can result in good line width roughness (LWR) and low exposure dose. Since the ligand leaving promoter can increase the crosslinking between metal oxide photoresist molecules, and the photoresist-strengthening material can diffuse into the photoresist or cover the surface of the photoresist, the photoresist can thus have a strengthened rigidity, resulting in a broken-free and peeling-free nano-pattern formed by the photoresist. The various aspects of the present disclosure will be discussed below in greater detail with reference to FIGS. 1A-12. First, a EUV lithography system will be discussed below with reference to FIGS. 1A, 1B, and 2. Next, the details of the photoresist including the ligand leaving promoter or the photoresist-strengthening material and the lithography process employing the photoresist including these materials will be discussed with reference to FIGS. 3-12.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

To address the trend of the Moore's law for decreasing size of chip components and the demand of higher computing power chips for mobile electronic devices such as smart phones with computer functions, multi-tasking capabilities, or even with workstation power. Smaller wavelength photolithography exposure systems are desirable. Extreme ultraviolet (EUV) photolithography technique uses an EUV radiation source to emit an EUV light ray with wavelength of about 13.5 nm. Because this wavelength is also in the x-ray radiation wavelength region, the EUV radiation source is also called a soft x-ray radiation source. The EUV light rays emitted from a LPP are collected by a collector mirror and reflected toward a patterned mask.

As shown in FIG. 1A, the EUV lithography system 10 includes an EUV radiation source 100 to generate EUV radiation, an exposure device 200, such as a scanner, and an excitation laser source 300. In some embodiments, the EUV radiation source 100 and the exposure device 200 are installed on a main floor MF of a clean room, while the excitation laser source 300 is installed in a base floor BF located under the main floor MF. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a photoresist layer to EUV light (also interchangeably referred to herein as EUV radiation). The photoresist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of LPP to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

FIG. 1B is a simplified schematic diagram of a detail of an extreme ultraviolet lithography tool according to an embodiment of the disclosure showing the exposure of photoresist coated substrate 210 secured on a substrate stage 208 of the exposure device 200 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to irradiate a patterning optic 205c, such as a reticle, with a beam of EUV light, to produce a patterned beam, and one or more reduction projection optics 205d, 205e, for projecting the patterned beam onto the photoresist coated substrate 210. A mechanical assembly (not shown) may be provided for generating a controlled relative movement between the photoresist coated substrate 210 and the patterning optic 205c. As further shown in FIG. 1A, the EUVL tool includes the EUV radiation source 100 including an EUV light radiator ZE emitting EUV light in a chamber 105 that is reflected by a collector 110 along a path into the exposure device 200 to irradiate the photoresist coated substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gradings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic,” as used herein, is directed to, but not limited to, components which operate solely or to advantage within one or more specific wavelength range(s) such as at the EUV output light wavelength, the irradiation laser wavelength, a wavelength suitable for metrology or any other specific wavelength.

In various embodiments of the present disclosure, the photoresist coated substrate 210 is a semiconductor wafer, such as a silicon wafer or other type of wafer to be patterned. The EUVL tool further includes other modules or is integrated with (or coupled with) other modules in some embodiments.

As shown in FIG. 1A, the EUV radiation source 100 includes a target droplet generator 115 and a collector 110, enclosed by a chamber 105. For example, the collector 110 is a laser-produced plasma (LPP) collector. In various embodiments, the target droplet generator 115 includes a reservoir to hold a source material and a nozzle 120 through which target droplets DP of the source material are supplied into the chamber 105.

In some embodiments, the target droplets DP are metal droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz).

Referring back to FIG. 1A, an excitation laser LR2 generated by the excitation laser source 300 is a pulse laser. The laser pulses LR2 are generated by the excitation laser source 300. The excitation laser source 300 may include a laser generator 310, laser guide optics 320 and a focusing apparatus 330. In some embodiments, the laser generator 310 includes a carbon dioxide (CO₂) or a neodymium-doped yttrium aluminum garnet (Nd:YAG) laser source with a wavelength in the infrared region of the electromagnetic spectrum. For example, the laser generator 310 has a wavelength of about 9.4 μm or about 10.6 μm, in an embodiment. The laser light LR1 generated by the laser generator 310 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In various embodiments, the pre-heat laser and the main laser have an average power in the range from about 1 kilowatt (kW) to about 50 kW. The pulse-frequency of the excitation laser LR2 is matched with (e.g., synchronized with) the ejection-frequency of the target droplets DP in an embodiment.

The excitation laser LR2 is directed through windows (or lenses) into the zone of excitation ZE in front of the collector 110. The windows are made of a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector 110. The collector 110 further reflects and focuses the EUV radiation for the lithography exposing processes performed through the exposure device 200. The droplet catcher 125 is used for catching excessive target droplets. For example, some target droplets may be purposely missed by the laser pulses.

In some embodiments, the collector 110 is designed with a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes a multilayer (ML), such as a plurality of Mo/Si film pairs, and may further include a capping layer (such as Ru) coated on the ML to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In the present disclosure, the terms mask, photomask, and reticle are used interchangeably. In the present embodiment, the patterning optic 205c is a reflective mask. The reflective mask also includes a reflective ML deposited on the substrate. The ML includes a plurality of film pairs, such as molybdenum-silicon (Mo/Si) film pairs (e.g., a layer of molybdenum above or below a layer of silicon in each film pair). Alternatively, the ML may include molybdenum-beryllium (Mo/Be) film pairs, or other suitable materials that are configurable to highly reflect the EUV light.

The patterning optic 205c may further include a capping layer, such as ruthenium (Ru), disposed on the ML for protection. The patterning optic 205c further includes an absorption layer deposited over the ML. The absorption layer is patterned to define a layer of an integrated circuit (IC), the absorber layer is discussed below in greater detail according to various aspects of the present disclosure. Alternatively, another reflective layer may be deposited over the ML and is patterned to define a layer of an integrated circuit, thereby forming a EUV phase shift mask.

The patterning optic 205c and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

One example of the patterning optic 205c (reflective mask) is shown in FIG. 2. The patterning optic 205c in the illustrated embodiment is a EUV mask, and includes a substrate 30 made of a LTEM. The LTEM material may include TiO₂ doped SiO₂, and/or other low thermal expansion materials known in the art. In some embodiments, a conductive layer 32 is additionally disposed under on the backside of the LTEM substrate 30 for the electrostatic chucking purpose. In one example, the conductive layer 32 includes chromium nitride (CrN), though other suitable compositions are possible.

The patterning optic 205c includes a reflective multilayer (ML) structure 34 disposed over the LTEM substrate 30. The ML structure 34 may be selected such that it provides a high reflectivity to a selected radiation type/wavelength. The ML structure 34 includes a plurality of film pairs, such as Mo/Si film pairs (e.g., a layer of molybdenum above or below a layer of silicon in each film pair). Alternatively, the ML structure 34 may include Mo/Be film pairs, or any materials with refractive index difference being highly reflective at EUV wavelengths.

Still referring to FIG. 2, the patterning optic 205c also includes a capping layer 36 disposed over the ML structure 34 to prevent oxidation of the ML. The patterning optic 205c may further include a buffer layer 38 disposed above the capping layer 36 to serve as an etching-stop layer in a patterning or repairing process of an absorption layer, which will be described later. The buffer layer 38 has different etching characteristics from the absorption layer disposed thereabove. The buffer layer 38 includes ruthenium (Ru), Ru compounds, such as RuB, RuSi, chromium (Cr), chromium oxide, chromium nitride, or combinations thereof.

The patterning optic 205c also includes an absorber layer 40 (also referred to as an absorption layer) formed over the buffer layer 38. In some embodiments, the absorber layer 40 absorbs the EUV radiation directed onto the mask. In various embodiments, the absorber layer may be made of tantalum boron nitride (TaBN), tantalum boron oxide (TaBO), or chromium (Cr), Radium (Ra), or a suitable oxide or nitride (or alloy) of one or more of the following materials: actium, radium, tellurium, zinc, copper, and aluminum.

FIGS. 3-12 are diagrammatic fragmentary cross-sectional side views of a semiconductor device at various stages of fabrication in accordance with various aspects of the present disclosure. The present disclosure provides a first embodiment shown in FIGS. 3, 4, 5A, 5B, and 7 and a second embodiment shown in FIGS. 3, 4, 6A, 6B, 6C, and 7. In some embodiments, the semiconductor device may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistor.

Reference is made to FIG. 3. A target layer 45 to be patterned is formed over a substrate 44. A photoresist layer 46 is coated over the target layer 45. A soft baking (SB) process S10 may be further applied to the photoresist layer 46 to reduce the solvent in the photoresist layer 46. For example, the solvent may be partially evaporated by the soft baking process.

In some embodiments, the substrate 44 may be a bulk semiconductor substrate including one or more semiconductor materials. In some embodiments, the substrate 44 may include silicon, silicon germanium, carbon doped silicon (Si:C), silicon germanium carbide, or other suitable semiconductor materials. In some embodiments, the substrate 44 is composed entirely of silicon. In some embodiments, the substrate 44 may include one or more epitaxial layers formed on a top surface of a bulk semiconductor substrate. In some embodiments, the one or more epitaxial layers introduce strains in the substrate 44 for performance enhancement. For example, the epitaxial layer includes a semiconductor material different from that of the bulk semiconductor substrate, such as a layer of silicon germanium overlying bulk silicon or a layer of silicon overlying bulk silicon geranium. In some embodiments, the epitaxial layer(s) incorporated in the substrate 44 are formed by selective epitaxial growth, such as, for example, metalorganic vapor phase epitaxy (MOVPE), molecular beam epitaxy (MBE), hydride vapor phase epitaxy (HYPE), liquid phase epitaxy (LPE), metal-organic molecular beam epitaxy (MOMBE), or combinations thereof. In some embodiments, the substrate 44 may be a semiconductor-on-insulator (SOI) substrate. In some embodiments, the SOI substrate includes a semiconductor layer, such as a silicon layer formed on an insulator layer. In some embodiments, the insulator layer is a buried oxide (BOX) layer including silicon oxide or silicon germanium oxide. The insulator layer is provided on a handle substrate such as, for example, a silicon substrate. In some embodiments, the SOI substrate is formed using separation by implanted oxygen (SIMOX) or other suitable technique, such as wafer bonding and grinding.

In some embodiments, the target layer 45 that can be patterned may also be referred to as a pattentable layer. In some embodiments, the target layer 45 serves as a hard mask layer including material(s) such as silicon oxide, silicon nitride, silicon oxynitride, or titanium nitride. In some embodiments, the target layer 45 severs as anti-reflection coating layer including nitrogen-free material(s), such as silicon oxide, silicon oxygen carbide, or plasma enhanced chemical vapor deposited silicon oxide. In some embodiments, the target layer 45 is substantially conductive or semi-conductive. The electrical resistance may be less than about 10³ ohm-meter. In some embodiments, the target layer 45 contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the target layer 45 may contain Cu, Ti, Al, Co, Ru, TiN, WN₂, or TaN. In some other embodiments, the target layer 45 contains a dielectric material with a dielectric constant in a range from about 1 to about 40. For example, the target layer 45 may contain SiO₂, silicon nitride, aluminum oxide, hafnium oxide, or lanthanum oxide. In some embodiments, the target layer 45 is formed by a deposition process such as, for example, chemical vapor deposition (CVD), physical vapor deposition (PVD), or plasma enhanced chemical vapor deposition (PECVD).

In some embodiments, the photoresist layer 46 is a metal oxide photoresist layer, in which the metal oxide photoresist layer includes a metal oxide core with organic ligands, a metal oxide framework with organic ligands, or a combination thereof. In some embodiments, the organic ligands are photo-cleavable ligand. In some embodiments, the photoresist layer 46 is a negative photoresist. The photoresist layer 46 has a composition including a solvent and a metal oxide material dissolved in the solvent, in which the metal oxide material includes metal oxide cores with organic ligands, metal oxide frameworks with organic ligands, or a combination thereof. The photoresist layer 46 may be formed by a spin-coating process. In some embodiments, the metal oxide core with organic ligands is an organometallic compound or precursor, such as transition metal complexes characterized with coordination numbers that range from 1 to 12. In some embodiments, the photoresist composition includes an organometallic material. In some embodiments, the photoresist composition is a negative tone development (NTD) photoresist including a metal core and two different organic ligands. A first ligand is a photo-cleavable ligand and the second ligand is a non-photo-cleavable ligand having a crosslinking group. When exposed to actinic radiation, the photoresist layer 46 undergoes one or more chemical reactions causing a change in solubility in a developer composition. During the exposure to actinic radiation, the metal core absorbs actinic radiation and generates a radical through metal core-ligand bond cleavage from the photo-cleavable ligand. In some embodiments, more secondary electrons are generated by photo excitation of the organometallic than a non-metallic organic compound because the binding energy of the electrons for the metal is lower. In addition, the metal core-ligand bond is also cleavable by secondary electron excitation. Radicals generated from the metal core-ligand bond cleavage initiate and trigger polymerization when the non-cleavable ligand on the metal has specific functional groups that can react with the radicals in some embodiments. Photoradical-assisted self-polymerization occurs, and not only metal oxides, but also organic crosslink frameworks form, providing much higher contrast and enabling a lower exposure dose to be used to pattern the photoresist layer 46.

In some embodiments, the metal oxide core and the metal oxide framework independently include Ti, Ir, Zn, Hf, Sn, Al, Cu, or combinations thereof. For example, the metal oxide core may include, but may not be limited to, hafnium oxide (HfO₂), zirconium oxide (ZrO₂), titanium oxide (TiO₂), tin oxide (SnO₂), or other suitable metal oxide. In some embodiments, the photo-cleavable ligand is an aliphatic or aromatic, cyclic or non-cyclic C1-C30 group, in which the C1-C30 group is unsubstituted or substituted with one or more selected from the group consisting of —I, —Br, —Cl, —F, —NH₂, —COOH, —OH, —SH, —S(═O)—, an alkenyl group, an alkynyl group, an imine group, an ether group, an ester group, an aldehyde group, a carbonyl group, an amide group, a sulfone group, an acetic acid group, a cyanide group, a hydroxyl group, an amine group, a phosphine group, a phosphite group, an aniline group, a pyridine group, and a pyrrole group.

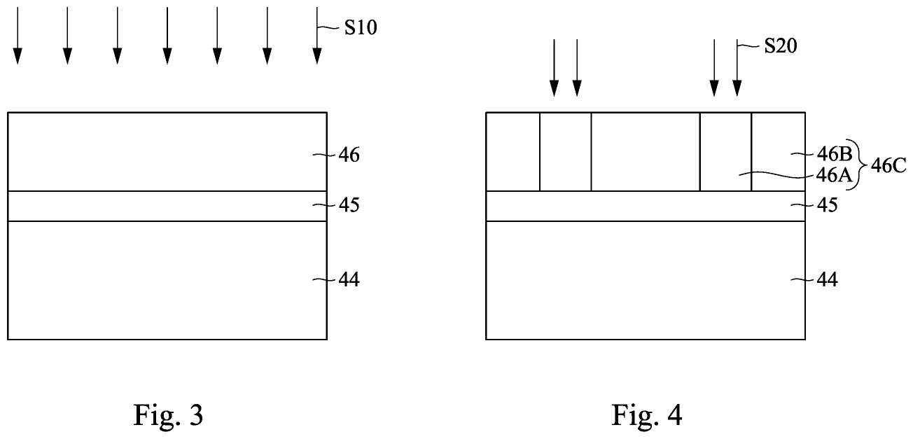

Referring to FIG. 4, an exposure process S20 is performed to expose a portion of the photoresist layer 46 to an EUV radiation to form an exposed photoresist layer 46C. In other words, the exposure process S20 applies the EUV radiation to the photoresist layer 46. The exposed photoresist layer 46C includes exposed portions 46A and unexposed portions 46B.

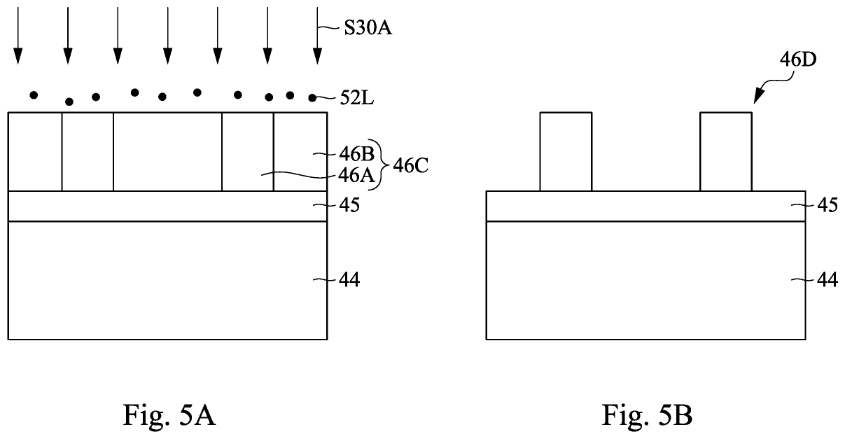

Referring to FIG. 5A, in an operation S30A, the exposed photoresist layer 46C is treated with a ligand leaving promoter 52L. In some embodiments, the ligand leaving promoter 52L includes a peroxide, a radical generator, or a combination thereof. The ligand leaving promoter 52L can promote metal ligand bond cleavage and therefore increase the crosslinking between metal oxide photoresist molecules. Accordingly, the exposed photoresist layer 46C can have higher degree of crosslinking, mechanical strength, and etch resistance.

In some embodiments, the ligand leaving promoter 52L is applied on the exposed photoresist layer 46C in a gaseous state, a liquid state, a solid state, or an aqueous state. For example, the ligand leaving promoter 52L is in a gaseous state, a liquid state, a solid state under 1 atm and 20° C. In some embodiments, the exposed photoresist layer 46C is treated by applying a solution including an organic solvent and the ligand leaving promoter 52L or water and the ligand leaving promoter 52L on the exposed photoresist layer 46C. In some embodiments, the operation S30A is performed by a solution-coating method, a sol-gel process, a chemical vapor deposition (CVD) process, a physical vapor deposition (PVD) process, an atomic layer deposition (ALD) process, the like, or combinations thereof. In some embodiments, the organic solvent includes a cyclic alcohol, a cyclic ketone, a cyclic ester, a cyclic ether, a cyclic amide, an aromatic ring, a cyclic alkane, or combinations thereof. In some other embodiments, the organic solvent includes propylene glycol methyl ether, propylene glycol methyl ether acetate, diacetone alcohol, methyl N-amyl ketone, butyl acetate, gamma-butyrolactone, cyclohexanone, toluene, 1-methyl-2-pyrrolidone, or combinations thereof.

In some embodiments, after performing the operation S30A, a post exposure baking (PEB) process may be applied to the exposed photoresist layer 46C to intensify the metal ligand bond cleavage reaction and dehydration of the metal oxide photoresist.

Furthermore, depending on a concentration or a nature of the ligand leaving promoter 52L, process parameters (e.g., a process time, a temperature, a chemical flow rate, and a number of loop to apply the ligand leaving promoter 52L) can be performed during or after applying the ligand leaving promoter (e.g., the operation S30A). In some embodiments, after performing the operation S30A or when performing the operation S30A, the exposed photoresist layer 46C is irradiated with light having a wavelength between 13 nm and 700 nm, such as 13, 20, 50, 100, 200, 300, 400, 500, 600, or 700 nm. In some embodiments, after performing the operation S30A or when performing the operation S30A, the exposed photoresist layer 46C is thermally baked at a temperature between 50° C. and 350° C., such as 50, 100, 150, 200, 250, 300, or 350° C. In some embodiments, the operation S30A is performed at 0° C. to 800° C., such as 0, 50, 100, 200, 300, 400, 500, 600, 700, or 800° C. For example, the ligand leaving promoter 52L is at a temperature from 0° C. to 800° C. For example, the whole structure shown in FIG. 5A is at a temperature from 0° C. to 800° C. The light and heat can accelerate the metal ligand bond cleavage reaction. In some embodiments, the operation S30A is performed for 5 seconds to 5 hours.

After the bonds between the ligands and the metal oxide cores or between the ligands and the metal oxide frameworks break, in the presence of peroxide, the metals in the metal oxide cores or the metal oxide frameworks tend to form bonds with oxygen atoms. For example, two metal atoms may form bonds with one oxygen atom. Therefore, the peroxide can promote metal ligand bond cleavage. In some embodiments, the peroxide includes oxygen, ozone, R—O—O—R′, or combinations thereof, R and R′ are independently H, an aryl group,

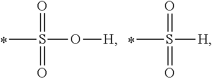

a branched, unbranched, or cyclic alkyl, alkenyl, or alkynyl, or a branched, unbranched, or cyclic alkyl, alkenyl, or alkynyl substituted with one or more functional groups including a hydroxyl group, an amine group, an epoxy group, an amide group, an ester group, a carboxyl group, a sulfate group, a sulfonyl group,

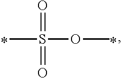

an ether group, a halogen group, a carbonyl group, or combinations thereof. For example, R and R′ may respectively have 1-20 carbon atoms, such as 1, 5, 10, 15, or 20 carbon atoms.

In some embodiments, the peroxide includes H—O—O—H, CH₃—O—O—H,

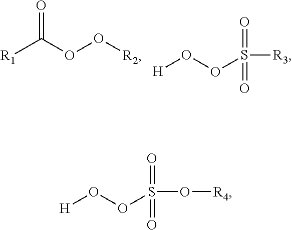

or combinations thereof, and R₁, R₂, R₃, and R₄ are independently H or a branched, unbranched, or cyclic alkyl, alkenyl, or alkynyl. For example, R₁, R₂, R₃, and R₄ may respectively have 1-20 carbon atoms, such as 1, 5, 10, 15, or 20 carbon atoms.

The radical generator may include an aryl group or a carbonyl group that easily generates a radical. Radicals can induce bond breakage between the ligands and the metals in the metal oxide cores or between the ligands and the metals in the metal oxide frameworks. In other words, the radicals can weaken the bond strength between the ligands and the metal oxide cores or between the ligands and the metal oxide frameworks. Therefore, the radical generator can promote metal ligand bond cleavage. In some embodiments, the radical generator includes an aromatic ring, a ketone, an alkoxyamine, a dialkyl hydroxylamine, an azo compound, or combinations thereof, the aromatic ring and the ketone are respectively substituted with one or more functional groups including an aryl group, a branched, unbranched, or cyclic alkyl, alkenyl, or alkynyl, or a branched, unbranched, or cyclic alkyl, alkenyl, or alkynyl substituted with one or more functional groups including a hydroxyl group, an amine group, an epoxy group, an amide group, an ester group, a carboxyl group, a sulfate group, a sulfonyl group,

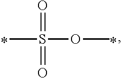

an ether group, a halogen group, a carbonyl group, an aryl group, or combinations thereof. For example, the functional group may have 1-20 carbon atoms, such as 1, 5, 10, 15, or 20 carbon atoms. For example, the alkoxyamine has a structure of

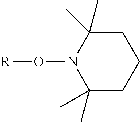

or R₃—O—NR₁R₂, in which R and R₃ are respectively an alkyl group, and R₁ and R₂ are respectively an alkyl group or an aryl group. For example, R and R₃ respectively include 1-10 carbon atoms. For example, the dialkyl hydroxylamine has a structure of

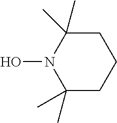

or HO—NR₁R₂, in which R₁ and R₂ are respectively an alkyl group or an aryl group. The alkoxyamine and the dialkyl hydroxylamine may generate aminoxyl radicals, such as

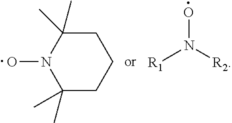

For example, the azo compound has a structure of R₁—N═N—R₂, in which R₁ and R₂ are respectively an alkyl group or an aryl group. For example, the azo compound has a structure of

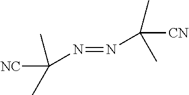

and may generate radicals, such as

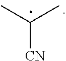

In some embodiments, the radical generator has a structure of

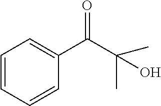

and may generate radicals, such as

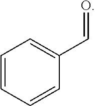

In some embodiments, the radical generator has a structure of

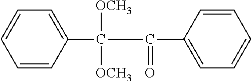 [SMILES: COC(OC)(C(=O)c1ccccc1)c1ccccc1]

and may generate radicals, such as

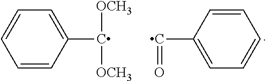

In some embodiments, the radical generator includes

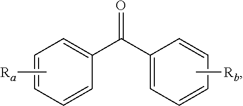

and Rₐ and R_{b} are independently H or a branched, unbranched, or cyclic alkyl, alkenyl, or alkynyl. For example, Rₐ and R_{b} may respectively have 1-20 carbon atoms, such as 1, 5, 10, 15, or 20 carbon atoms.

In FIG. 5B, the exposed photoresist layer 46C is developed, and the exposed portions 46A remain on the target layer 45 to form a patterned photoresist 46D. After developing the exposed photoresist layer 46C, an optional hard bake (HB) may be performed, in which the hard bake serves to improve the insolubility of the patterned photoresist 46D.

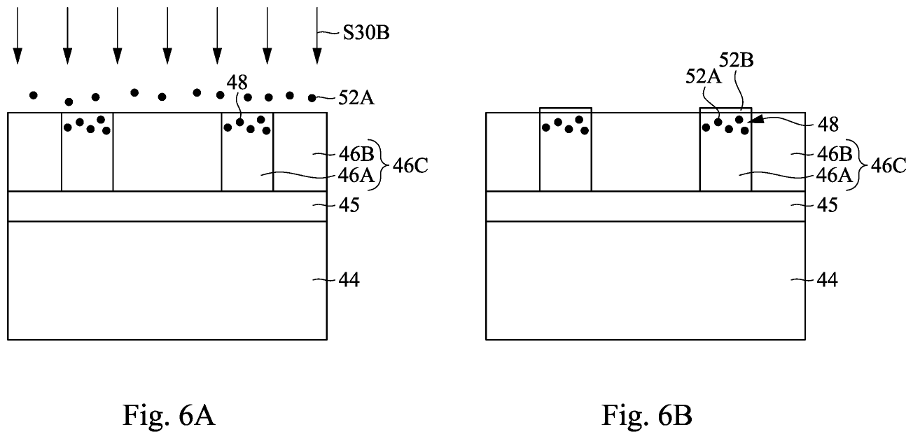

In FIGS. 6A-6C, the present disclosure provides another embodiment for treating the exposed photoresist layer 46C shown in FIG. 4. Please refer to FIG. 4 and FIG. 6A. As shown in FIG. 4, the exposure process S20 is performed to expose a portion of the photoresist layer 46 to an EUV radiation to form the exposed photoresist layer 46C. Since the metal core-ligand bonds are broken by the EUV radiation, after the ligand cleavage, the exposed photoresist layer 46C has a plurality of pores 48 near the surface receiving the EUV radiation as shown in FIG. 6A in some embodiments. Therefore, in order to improve the mechanical strength and etch resistance of the exposed photoresist layer 46C, the exposed photoresist layer 46C is treated with a photoresist-strengthening material 52A in an operation S30B as shown in FIG. 6A.

Referring to FIG. 6A and FIG. 6B, by the operation S30B, a photoresist-strengthening material 52A is filled into the pores 48 as shown in FIG. 6B. In some embodiments, a coating layer 52B including the photoresist-strengthening material 52A is also formed on the exposed portions 46A. In some embodiments, the photoresist-strengthening material 52A includes a silane, a metal oxide, or a combination. During the exposure process, the organic ligands in the exposed portions 46A may leave from the metal oxide cores and/or the metal oxide frameworks, and therefore the exposed portions 46A becomes more hydrophilic than the unexposed portions 46B. Accordingly, the photoresist-strengthening material 52A tends to cover on the exposed portions 46A to form the coating layer 52B and diffuse or infiltrate into the pores 48. After treatment, the exposed portions 46A can have better resistance toward a developer (including water-based and solvent-based mixture solution), an etching gas, and/or an ion/atom bombardment.

In some embodiments, the photoresist-strengthening material 52A is applied on the exposed photoresist layer 46C in a gaseous state, a liquid state, a solid state, or an aqueous state. For example, the photoresist-strengthening material 52A is in a gaseous state, a liquid state, a solid state under 1 atm and 20° C. In some embodiments, filling the photoresist-strengthening material 52A into the pores 48 and/or forming the coating layer 52B on the exposed portions 46A includes applying a solution including an organic solvent and the photoresist-strengthening material 52A or water and the photoresist-strengthening material 52A on the exposed photoresist layer 46C. In some embodiments, the operation S30B is performed by a solution-coating method, a sol-gel process, a chemical vapor deposition (CVD) process, a physical vapor deposition (PVD) process, an atomic layer deposition (ALD) process, the like, or combinations thereof. In some embodiments, the organic solvent includes a cyclic alcohol, a cyclic ketone, a cyclic ester, a cyclic ether, a cyclic amide, an aromatic ring, a cyclic alkane, or combinations thereof. In some other embodiments, the organic solvent includes propylene glycol methyl ether, propylene glycol methyl ether acetate, diacetone alcohol, methyl N-amyl ketone, butyl acetate, gamma-butyrolactone, cyclohexanone, toluene, 1-methyl-2-pyrrolidone, or combinations thereof.

In some embodiments, after the operation S30B, a post exposure baking (PEB) process may be applied to the exposed photoresist layer 46C to intensify the metal ligand bond cleavage reaction and dehydration of the metal oxide photoresist.

Furthermore, depending on a concentration or a nature of the photoresist-strengthening material 52A, process parameters (e.g., a process time, a temperature, a chemical flow rate, and a number of loop to apply the photoresist-strengthening material 52A) can be performed during or after applying the photoresist-strengthening material 52A (e.g., the operation S30B). In some embodiments, after performing the operation S30B or when performing the operation S30B, the exposed photoresist layer 46C is irradiated with light having a wavelength between 13 nm and 700 nm, such as 13, 20, 50, 100, 200, 300, 400, 500, 600, or 700 nm. In some embodiments, after performing the operation S30B or when performing the operation S30B, the exposed photoresist layer 46C is thermally baked at a temperature between 50° C. and 800° C., such as 50, 100, 200, 300, 400, 500, 600, 700, or 800° C. In some other embodiments, the operation S30B is performed at 0° C. to 800° C., such as 0, 50, 100, 200, 300, 400, 500, 600, 700, or 800° C. For example, the photoresist-strengthening material 52A is at a temperature from 0° C. to 800° C. For example, the whole structure shown in FIG. 5A is at a temperature from 0° C. to 800° C. The light and heat can accelerate the metal ligand bond cleavage reaction. In some embodiments, the operation S30B is performed for 5 seconds to 5 hours.

In some embodiments, the photoresist-strengthening material 52A includes a silane having a formula of RₐSiX_{b}, a sum of a and b is equal to 4, R is a branched, unbranched, or cyclic alkyl, alkenyl, or alkynyl, or a branched, unbranched, or cyclic alkyl, alkenyl, or alkynyl substituted with one or more functional groups including a hydroxyl group, an amine group, an epoxy group, an amide group, an ester group, a carboxyl group, a sulfate group, a sulfonyl group,

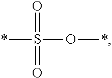

an ether group, a halogen group, a carbonyl group, an aryl group, or an organometallic complex, and X is a halogen group, an alkoxy group, or a fluoroalkoxy group. A degree of intermolecular crosslinking thereof can be adjusted by X and a number of X (i.e., b). For example, R may have 1-20 carbon atoms, such as 1, 5, 10, 15, or 20 carbon atoms.

In some embodiments, the photoresist-strengthening material further includes a photobase generator, a photoacid generator, a thermal base generator, a thermal acid generator, or combinations thereof, and these generators can be used as a catalyst to increase the crosslinking of the silane. For example, the photobase generator has a structure of

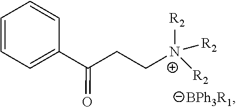

in which R₁ and R₂ are respectively a C1-C10 alkyl group. For example, the photoacid generator has a structure of

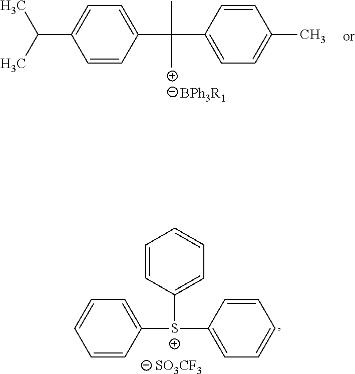

in which R₁ is a C1-C10 alkyl group. For example, the thermal base generator has a structure of

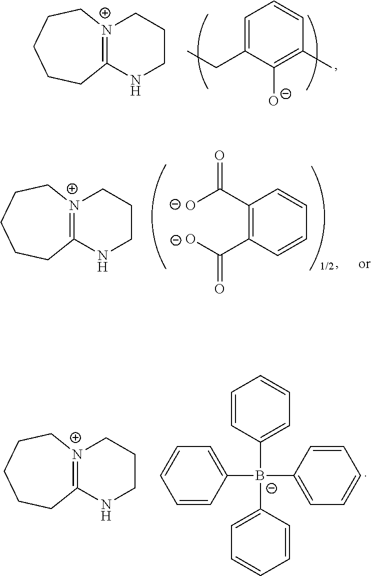

For example, the thermal acid generator has a structure of

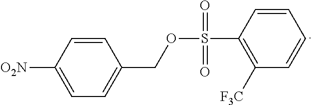 [SMILES: O=[N+]([O-])c1ccc(COS(=O)(=O)c2ccccc2C(F)(F)F)cc1]

In some embodiments, the photoresist-strengthening material further includes a photobase generator, a photoacid generator, a thermal base generator, a thermal acid generator, or combinations thereof and a linker material, such as tetramethylolglycoluril (TMGU), epoxy, azide, or combinations thereof, to increase the crosslinking of the silane.

In some embodiments, the metal oxide includes Sn, Ti, Zr, Hf, Zn, Al, or Cu. In some embodiments, the photoresist-strengthening material 52A includes a metal oxide including RₐSn_{b}O_{c}R′_{d}Xₑ, RₐTi_{b}O_{c}R′_{d}Xₑ, RₐHf_{b}O_{c}R′_{d}Xₑ, RₐZn_{b}O_{c}R′_{d}Xₑ, RₐAl_{b}O_{c}R′_{d}Xₑ, or RₐCu_{b}O_{c}R′_{d}Xₑ, R is a mono-dentate organic ligand or a multi-dentate organic ligand including an amide, a carboxyl group, an aryl group, a branched, unbranched, or cyclic alkyl, alkenyl, or alkynyl, a branched, unbranched, or cyclic alkyl, alkenyl, or alkynyl substituted with a carbonyl group, or a derivative thereof substituted with a halogen group, R′ is H or an organic ligand including an amide, a carboxyl group, an aryl group, a branched, unbranched, or cyclic alkyl, alkenyl, or alkynyl, a branched, unbranched, or cyclic alkyl, alkenyl, or alkynyl substituted with a carbonyl group, or a derivative thereof substituted with a halogen group, X is a halide anion or a carboxylic anion, and a sum of a, c, d and e equals to a multiplied value obtained by multiplying b and an oxidation number of a metal of the metal oxide. In some embodiments, the photoresist-strengthening material 52A can be made of a solution prepared by dissolving metal oxide clusters or metal oxide monomers in a solvent (e.g., organic solvent or water). The metal oxide clusters or the metal oxide monomers include RₐSn_{b}O_{c}R′_{d}Xₑ, RₐTi_{b}O_{c}R′_{d}Xₑ, RₐZr_{b}O_{c}R′_{d}Xₑ, RₐHf_{b}O_{c}R′_{d}Xₑ, RₐZn_{b}O_{c}R′_{d}Xₑ, RₐAl_{b}O_{c}R′_{d}Xₑ, or RₐCu_{b}O_{c}R′_{d}Xₑ. For example, R and R′ may respectively have 1-20 carbon atoms, such as 1, 5, 10, 15, or 20 carbon atoms.

Referring to FIG. 6C, after filling the photoresist-strengthening material 52A into the plurality of pores 48 and/or after forming the coating layer 52B on the exposed portions 46A, the exposed photoresist layer 46C is developed to form a patterned photoresist 46E. The patterned photoresist 46E includes the exposed portions 46A, the photoresist-strengthening material 52A, and the coating layer 52B. After developing the exposed photoresist layer 46C, an optional hard bake (HB) may be performed, in which the hard bake serves to improve the insolubility of the patterned photoresist 46E.

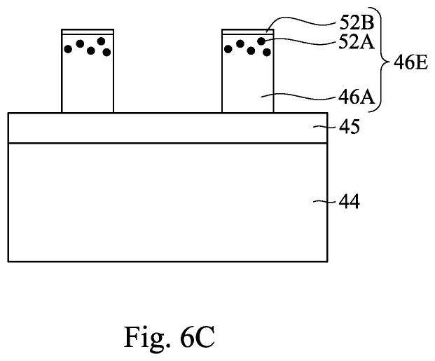

Please refer to FIG. 5B and FIG. 7. The target layer 45 can be etched by using the patterned photoresist 46D as an etching mask. Since the patterned photoresist 46D is treated by the ligand leaving promoter 52L, the patterned photoresist 46D has a higher degree of crosslinking, mechanical strength, and etch resistance. Please refer to FIG. 6C and FIG. 7. Since the photoresist-strengthening material 52A is filled into the patterned photoresist 46E and/or coated on the exposed portions 46A, the patterned photoresist 46E has higher mechanical strength and etch resistance. Therefore, delicate patterns can be formed in the target layer 45 by the patterned photoresist 46D or the patterned photoresist 46E.

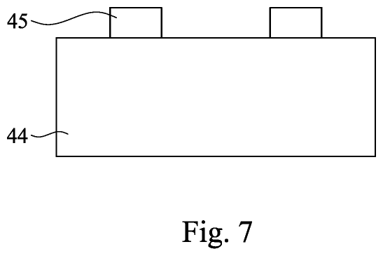

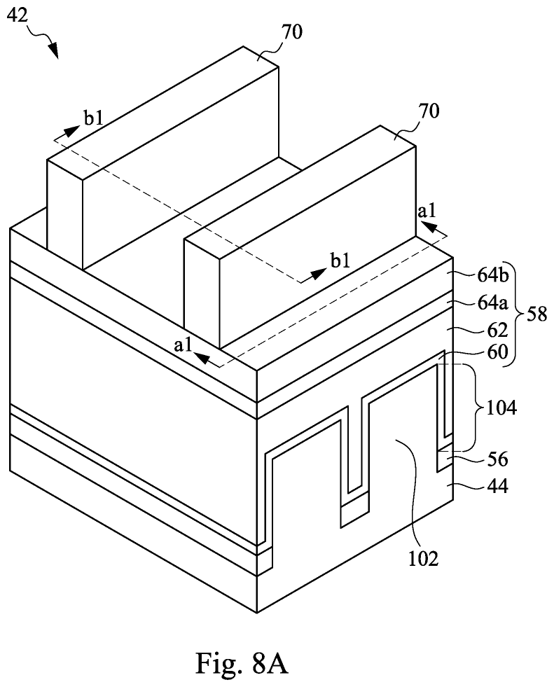

FIG. 8A is a perspective view of the semiconductor device 42 at various stages of fabrication in accordance with various aspects of the present disclosure. FIG. 8B is a cross-sectional view of the semiconductor device 42 taken along a line a1-a1 of FIG. 8A. FIG. 8C is a cross-sectional view of the semiconductor device 42 taken along a line b1-b1 of FIG. 8A. FIGS. 9-12 are diagrammatic fragmentary cross-sectional side views of the semiconductor device 42 at various stages of fabrication in accordance with various aspects of the present disclosure. Referring to FIGS. 8A-8C, a dummy gate stack 58 is formed on top surfaces and sidewalls of the protruding fins 104 of the semiconductor strips 102. The dummy gate stack 58 may include a dummy gate dielectric 60 and a dummy gate electrode 62 on the dummy gate dielectric 60. The dummy gate dielectric 60 may be, for example, silicon oxide, silicon nitride, a combination thereof, or the like, and may be deposited or thermally grown according to acceptable techniques.

The dummy gate electrode 62 may be deposited over the dummy gate dielectric 60 and then planarized, such as by a CMP. The dummy gate electrode 62 may be deposited by PVD, CVD, sputter deposition, or other techniques for depositing the selected material. The dummy gate electrode 62 may be formed, for example, using polysilicon, and other materials may also be used. The dummy gate electrode 62 may be made of other materials that have a high etching selectivity from the etching of STI regions 56. The dummy gate stack 58 may also include hard mask layers 64a and 64b over the dummy gate electrode 62. The hard mask layers 64a and 64b may be formed of silicon nitride and silicon oxide, respectively. The dummy gate stack 58 may cross over a single one or a plurality of protruding fins 104 and/or STI regions 56.

A patterned mask 70 is formed on the dummy gate stack 58. The above discussions of the patterned photoresist 46D or the patterned photoresist 46E apply to the patterned mask 70, unless mentioned otherwise. In other words, the patterned mask 70 can be formed by the embodiments shown in FIGS. 3-7. Therefore, the patterned mask 70 has a strengthened rigidity, resulting in a broken-free and peeling-free nano-pattern formed by the patterned mask 70.

In FIG. 9, using the patterned mask 70 as a mask, the pattern of the patterned mask 70 are extended into the dummy gate stack 58 by etching, using one or more suitable etchants. The patterned mask 70 is at least partially removed during the etching operation in some embodiments. In other embodiments, the patterned mask 70 is removed after etching the dummy gate stack 58 by using a suitable photoresist stripper solvent or by a photoresist ashing operation.

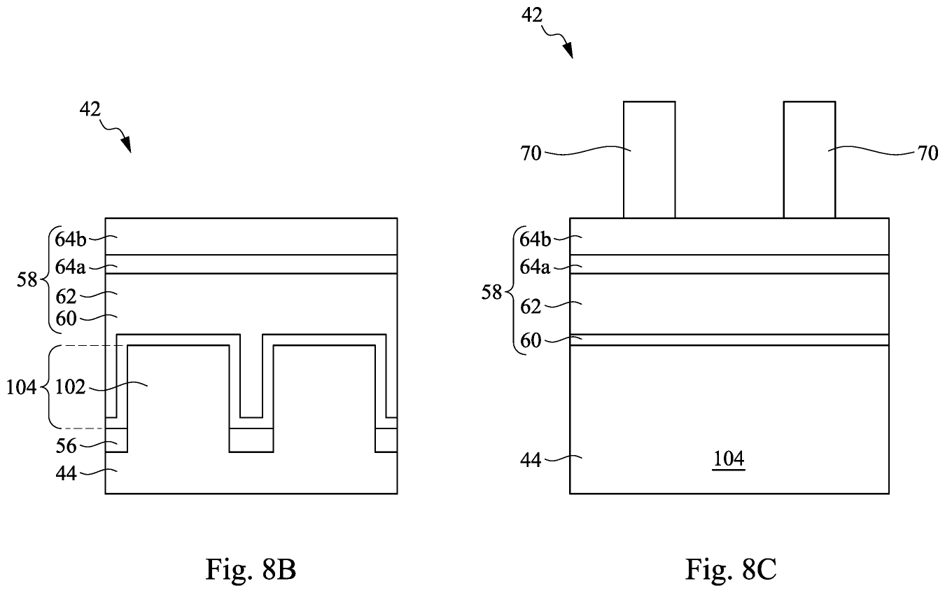

Next, as illustrated in FIG. 10, gate spacers 72 are formed on sidewalls of the dummy gate stack 58. In some embodiments of the gate spacer formation step, a spacer material layer is deposited on the substrate 44 and the dummy gate stack 58. The spacer material layer may be a conformal layer that is subsequently etched back to form gate spacers 72. The spacer material layer is made of a low-k dielectric material. The low-k dielectric material has a dielectric constant (k value) of lower than about 3.5. Suitable materials for the low-k dielectric material may include, but are not limited to, doped silicon dioxide, fluorinated silica glass (FSG), carbon-doped silicon dioxide, porous silicon dioxide, porous carbon-doped silicon dioxide, SiLK™ (an organic polymeric dielectric distributed by Dow Chemical of Michigan), Black Diamond (a product of Applied Materials of Santa Clara, Calif.), Xerogel, Aerogel, amorphous fluorinated carbon, Parylene, bis-benxocyclocutenes (BCB), polyimide, polynoroboneses, benzocyclocutene, PTFE, porous SiLK, hydrogen silsesquioxane (HSQ), methylsilsesquioxane (MSQ), and/or combinations thereof. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate stack 58 (e.g., in source/drain regions of the fins 104). Portions of the spacer material layer directly above the dummy gate stack 58 may be completely removed by this anisotropic etching process. Portions of the spacer material layer on sidewalls of the dummy gate stack 58 may remain, forming gate spacers, which are denoted as the gate spacers 72, for the sake of simplicity. In some embodiments, the gate spacers 72 may be used to offset subsequently formed doped regions, such as source/drain regions. The gate spacers 72 may further be used for designing or modifying the source/drain region profile.

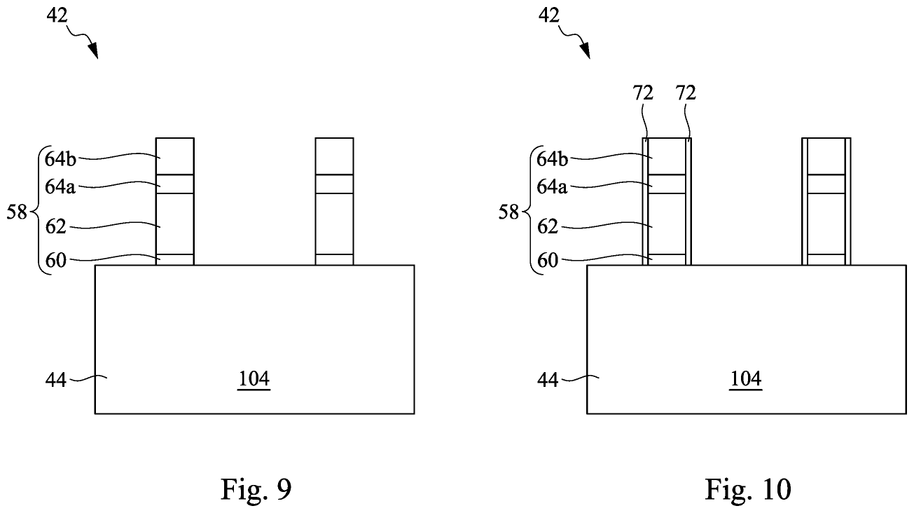

In FIG. 11, after formation of the gate spacers 72 is completed, source/drain epitaxial structures 74 are formed on source/drain regions of the protruding fins 104 that are not covered by the dummy gate stack 58 and the gate spacers 72. In some embodiments, formation of the source/drain epitaxial structures 74 includes recessing source/drain regions of the fins 104, followed by epitaxially growing semiconductor materials in the recessed source/drain regions of the fins 104. The source/drain epitaxial structures 74 are on opposite sides of the dummy gate stack 58.

The source/drain regions of the fins 104 can be recessed using suitable selective etching processing that attacks the fins 104, but hardly attacks the gate spacers 72 and the hard mask layer 64b of the dummy gate stack 58. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 72 and the hard mask layer 64b of the dummy gate stack 58. In some other embodiments, recessing the protruding fins 104 may be performed by a wet chemical etch, such as ammonium peroxide mixture (APM), NH₄OH, tetramethylammonium hydroxide (TMAH), combinations thereof, or the like, which etches the fins 104 at a faster etch rate than it etches the gate spacers 72 and the hard mask layer 64b of the dummy gate stack 58. In some other embodiments, recessing the protruding fins 104 may be performed by a combination of a dry chemical etch and a wet chemical etch.

Once recesses are created in the source/drain regions of the fins 104, source/drain epitaxial structures 74 are formed in the source/drain recesses in the fins 104 by using one or more epitaxy or epitaxial (epi) processes that provides one or more epitaxial materials on the protruding fins 104. During the epitaxial growth process, the gate spacers 72 limit the one or more epitaxial materials to source/drain regions in the fins 104. In some embodiments, the lattice constants of the source/drain epitaxial structures 74 are different from the lattice constant of the fins 104, so that the channel region in the fins 104 and between the source/drain epitaxial structures 74 can be strained or stressed by the source/drain epitaxial structures 74 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 74 may include Ge, Si, GaAs, AlGaAs, SiGe, GaAsP, SiP, or other suitable material. The source/drain epitaxial structures 74 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 74 are not in-situ doped, an implantation process (i.e., a junction implant process) is performed to dope the source/drain epitaxial structures 74. In some exemplary embodiments, the source/drain epitaxial structures 74 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 74 are formed, an annealing process can be performed to activate the p-type dopants or n-type dopants in the source/drain epitaxial structures 74. The annealing process may be, for example, a rapid thermal anneal (RTA), a laser anneal, a millisecond thermal annealing (MSA) process or the like.

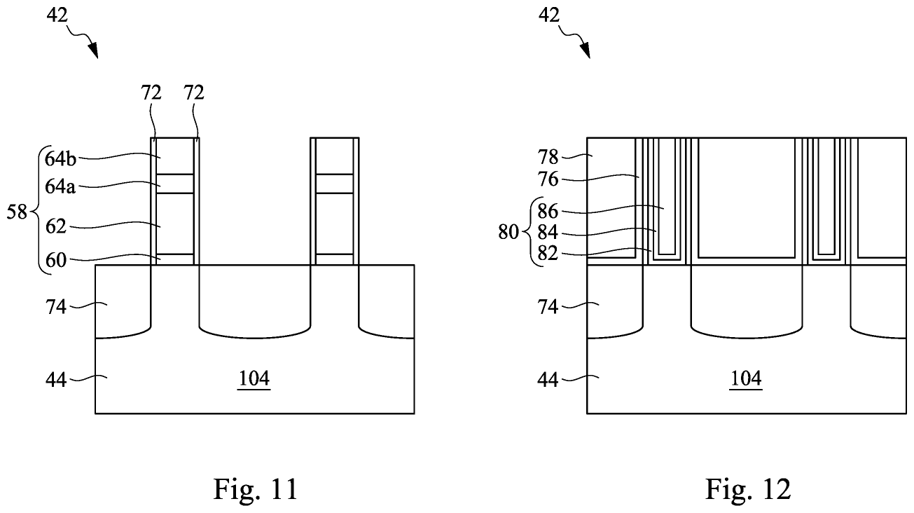

Next, in FIG. 12, a contact etch stop layer (CESL) 76 and an interlayer dielectric (ILD) layer 78 are formed on the substrate 44 in sequence. In some examples, the CESL 76 includes a silicon nitride layer, silicon oxide layer, a silicon oxynitride layer, and/or other suitable materials having a different etch selectivity than the ILD layer 78. The CESL 76 may be formed by plasma-enhanced chemical vapor deposition (PECVD) process and/or other suitable deposition or oxidation processes. In some embodiments, the ILD layer 78 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 76. The ILD layer 78 may be deposited by a PECVD process or other suitable deposition technique. In some embodiments, after formation of the ILD layer 78, the wafer may be subject to a high thermal budget process to anneal the ILD layer 78.

In some examples, after forming the ILD layer 78, a planarization process may be performed to remove excessive materials of the ILD layer 78 and the CESL 76. For example, a planarization process includes a chemical mechanical planarization (CMP) process which removes portions of the ILD layer 78 and the CESL 76 overlying the dummy gate stack 58. In some embodiments, the CMP process also removes hard mask layers 64a and 64b (as shown in FIG. 11) and exposes the dummy gate electrode 62.

An etching process is performed to remove the dummy gate electrode 62 and the dummy gate dielectric 60, resulting in gate trenches between corresponding gate spacers 72. The dummy gate stack 58 are removed using a selective etching process (e.g., selective dry etching, selective wet etching, or a combination thereof) that etches materials in the dummy gate stack 58 at a faster etch rate than it etches other materials (e.g., gate spacers 72 and/or the ILD layer 78).

Thereafter, a high-k/gate structures 80 (i.e., replacement gate structures) are respectively formed in the gate trenches. The high-k/gate structures 80 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack; however other compositions are possible. In some embodiments, each of the high-k/gate structures 80 forms the gate associated with the three-sides of the channel region provided by the fin 104. Stated another way, each of the high-k/gate structures 80 wraps around the fin 104 on three sides. In various embodiments, the high-k/gate structure 80 includes a gate dielectric layer 82 lining the gate trench, a work function metal layer 84 formed over the gate dielectric layer 82, and a fill metal 86 formed over the work function metal layer 84 and filling a remainder of gate trenches. The gate dielectric layer 82 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 84 and/or the fill metal 86 used within high-k/gate structures 80 may include a metal, metal alloy, or metal silicide. Formation of the high-k/gate structures 80 may include multiple deposition processes to form various gate materials, one or more liner layers, and one or more CMP processes to remove excessive gate materials.

In some embodiments, the interfacial layer of the gate dielectric layer 82 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 82 may include hafnium oxide (HfO₂). Alternatively, the gate dielectric layer 82 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 84 may include work function metals to provide a suitable work function for the high-k/gate structures 80. For an n-type FinFET, the work function metal layer 84 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 84 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 86 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 42 includes other layers or features not specifically illustrated. In some embodiments, back end of line (BEOL) processes are performed on the semiconductor device 42. In some embodiments, the semiconductor device 42 is formed by a non-replacement metal gate process or a gate-first process.

Based on the above discussions, it can be seen that the present disclosure offers the methods for treating the photoresist. The ligand leaving promoter and the photoresist-strengthening material can react with, adsorb on, or infiltrate the photoresist, and therefore the dose-to-size (exposure dose) can be reduce more than 3%. The exposed portions of the photoresist can have better resistance toward a developer (including water-based and solvent-based mixture solution), an etching gas, and/or an ion/atom bombardment. In other words, the exposed portions of the photoresist can have excellent etch resistance. Furthermore, since the mechanical strength of the exposed portions of the photoresist is increased, after development, the exposed portions (patterns) do not easily collapse, the pattern fidelity can be enhanced, and pattern wiggling can be reduce during a pattern transferring process, such as ion/atom bombardment and/or etching process.

In some embodiments, a method of manufacturing a semiconductor device includes the following operations. A metal oxide photoresist layer is formed over a target layer. The metal oxide photoresist layer includes a metal oxide core with organic ligands, a metal oxide framework with organic ligands, or a combination thereof. The metal oxide photoresist layer is exposed to an extreme ultraviolet (EUV) radiation. The metal oxide photoresist layer is treated with a ligand leaving promoter. The metal oxide photoresist layer is developed to form a patterned photoresist. The target layer is etched by using the patterned photoresist as an etching mask.

In some embodiments, a method of manufacturing a semiconductor device includes the following operations. A photoresist layer is formed over a target layer. The photoresist layer is exposed to form an exposed photoresist layer including a plurality of pores. A photoresist-strengthening material is filled into the plurality of pores. After filling the photoresist-strengthening material into the plurality of pores, the exposed photoresist layer is developed to form a patterned photoresist. The target layer is etched by using the patterned photoresist as an etching mask.

In some embodiments, a method of manufacturing a semiconductor device includes the following operations. A photoresist layer is formed over a target layer. The photoresist layer is exposed to form an exposed photoresist layer having at least one exposed portion. A coating layer is formed on the at least one exposed portion. After forming the coating layer on the at least one exposed portion, the exposed photoresist layer is developed to form a patterned photoresist. The target layer is etched by using the patterned photoresist as an etching mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a metal oxide photoresist layer over a target layer, wherein the metal oxide photoresist layer comprises a metal oxide core with organic ligands, a metal oxide framework with organic ligands, or a combination thereof;
exposing the metal oxide photoresist layer to an extreme ultraviolet (EUV) radiation;
treating the metal oxide photoresist layer with a ligand leaving promoter;
developing the metal oxide photoresist layer to form a patterned photoresist; and
etching the target layer by using the patterned photoresist as an etching mask.

2. The method of claim 1, wherein the ligand leaving promoter comprises a peroxide, a radical generator, or a combination thereof.

3. The method of claim 2, wherein the peroxide comprises oxygen, ozone, R—O—O-—R′, or combinations thereof, R and R′ are independently H, an aryl group, 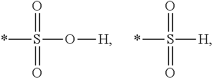
a branched, unbranched, or cyclic alkyl, alkenyl, or alkynyl, or a branched, unbranched, or cyclic alkyl, alkenyl, or alkynyl substituted with one or more functional groups comprising a hydroxyl group, an amine group, an epoxy group, an amide group, an ester group, a carboxyl group, a sulfate group, a sulfonyl group, 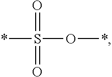
an ether group, a halogen group, a carbonyl group, or combinations thereof.

4. The method of claim 3, wherein the peroxide comprises H—O—O—H, CH₃—O—O—H, 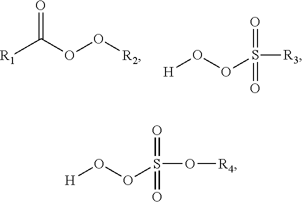
or combinations thereof, and R₁, R₂, R₃, and R₄ are independently H or a branched, unbranched, or cyclic alkyl, alkenyl, or alkynyl.

5. The method of claim 2, wherein the radical generator comprises an aromatic ring, a ketone, an alkoxyamine, a dialkyl hydroxylamine, an azo compound, or combinations thereof, the aromatic ring and the ketone are respectively substituted with one or more functional groups comprising an aryl group, a branched, unbranched, or cyclic alkyl, alkenyl, or alkynyl, or a branched, unbranched, or cyclic alkyl, alkenyl, or alkynyl substituted with one or more functional groups comprising a hydroxyl group, an amine group, an epoxy group, an amide group, an ester group, a carboxyl group, a sulfate group, a sulfonyl group, 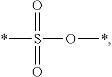
an ether group, a halogen group, a carbonyl group, an aryl group, or combinations thereof.

6. The method of claim 5, wherein the radical generator comprises 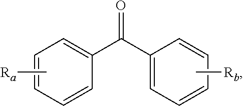
and Rₐ and R_{b} are independently H or a branched, unbranched, or cyclic alkyl, alkenyl, or alkynyl.

7. The method of claim 1, further comprising after treating the metal oxide photoresist layer with the ligand leaving promoter or when treating the metal oxide photoresist layer with the ligand leaving promoter, irradiating the metal oxide photoresist layer with light having a wavelength between 13 nm and 700 nm or thermally baking the metal oxide photoresist layer at a temperature between 50° C. and 350° C.

8. A method of manufacturing a semiconductor device, comprising:
forming a photoresist layer over a target layer;
exposing the photoresist layer to form an exposed photoresist layer comprising a plurality of pores;
filling a photoresist-strengthening material into the plurality of pores;
after filling the photoresist-strengthening material into the plurality of pores, developing the exposed photoresist layer to form a patterned photoresist; and
etching the target layer by using the patterned photoresist as an etching mask.

9. The method of claim 8, wherein the photoresist-strengthening material comprises a silane having a formula of RₐSiX_{b}, a sum of a and b is equal to 4, R is a branched, unbranched, or cyclic alkyl, alkenyl, or alkynyl, or a branched, unbranched, or cyclic alkyl, alkenyl, or alkynyl substituted with one or more functional groups comprising a hydroxyl group, an amine group, an epoxy group, an amide group, an ester group, a carboxyl group, a sulfate group, a sulfonyl group, 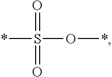
an ether group, a halogen group, a carbonyl group, an aryl group, or an organometallic complex, and X is a halogen group, an alkoxy group, or a fluoroalkoxy group.

10. The method of claim 9, wherein the photoresist-strengthening material further comprises a photobase generator, a photoacid generator, a thermal base generator, a thermal acid generator, or combinations thereof.

11. The method of claim 8, wherein the photoresist-strengthening material comprises a metal oxide comprising RₐSn_{b}O_{c}R′_{d}Xₑ, RₐTi_{b}O_{c}R′_{d}Xₑ, RₐZr_{b}O_{c}R′_{d}Xₑ, RₐHf_{b}O_{c}R′_{d}Xₑ, RₐZn_{b}O_{c}R′_{d}Xₑ, RₐAl_{b}O_{c}R′_{d}Xₑ, or RₐCu_{b}O_{c}R′_{d}Xₑ, R is a mono-dentate organic ligand or a multi-dentate organic ligand comprising an amide, a carboxyl group, an aryl group, a branched, unbranched, or cyclic alkyl, alkenyl, or alkynyl, a branched, unbranched, or cyclic alkyl, alkenyl, or alkynyl substituted with a carbonyl group, or a derivative thereof substituted with a halogen group, R′ is H or an organic ligand comprising an amide, a carboxyl group, an aryl group, a branched, unbranched, or cyclic alkyl, alkenyl, or alkynyl, a branched, unbranched, or cyclic alkyl, alkenyl, or alkynyl substituted with a carbonyl group, or a derivative thereof substituted with a halogen group, X is a halide anion or a carboxylic anion, and a sum of a, c, d and e equals to a multiplied value obtained by multiplying b and an oxidation number of a metal of the metal oxide.

12. The method of claim 8, wherein filling the photoresist-strengthening material into the plurality of pores is performed by using a solution-coating method, a sol-gel process, a chemical vapor deposition (CVD) process, a physical vapor deposition (PVD) process, or an atomic layer deposition (ALD) process.

13. The method of claim 8, further comprising after filling the photoresist-strengthening material into the plurality of pores or when filling the photoresist-strengthening material into the plurality of pores, irradiating the photoresist layer with light having a wavelength between 13 nm and 700 nm or thermally baking the photoresist layer at a temperature between 50° C. and 800° C.

14. The method of claim 8, wherein filling the photoresist-strengthening material into the plurality of pores comprises applying the photoresist-strengthening material in a gaseous state.

15. The method of claim 8, wherein filling the photoresist-strengthening material into the plurality of pores comprises applying a solution comprising an organic solvent and the photoresist-strengthening material or water and the photoresist-strengthening material on the photoresist layer.

16. The method of claim 15, wherein the organic solvent comprises a cyclic alcohol, a cyclic ketone, a cyclic ester, a cyclic ether, a cyclic amide, an aromatic ring, a cyclic alkane, or combinations thereof.

17. A method of manufacturing a semiconductor device, comprising:
forming a photoresist layer over a target layer;
exposing the photoresist layer to form an exposed photoresist layer having at least one exposed portion;
forming a coating layer on the at least one exposed portion;
after forming the coating layer on the at least one exposed portion, developing the exposed photoresist layer to form a patterned photoresist; and
etching the target layer by using the patterned photoresist as an etching mask.

18. The method of claim 17, wherein the coating layer comprises a silane, a metal oxide, or a combination.

19. The method of claim 18, wherein the metal oxide comprises Sn, Ti, Zr, Hf, Zn, Al, or Cu.

20. The method of claim 18. wherein forming the coating layer on the at least one exposed portion comprises applying a solution comprising the silane or the metal oxide and an organic solvent or water.
